(19) United States
(12) Patent Application Publication
(10) Pub. No.: US 2011/0121247 A1
(43) Pub. Date: May 26, 2011

(54) FAULT MONITORING SYSTEM FOR ELECTRIC SINGLE OR POLY-PHASE CHAIN HOIST MOTORS

(75) Inventors: Daniel L. Houser, Apopka, FL (US); John J. Owshanik, Marco Island, FL (US); John F. Owshanik, Longwood, FL (US)

(73) Assignee: Real Rigging Solutions, LLC, Longwood, FL (US)

(21) Appl. No.: 12/913,817

(22) Filed: Oct. 28, 2010

Related U.S. Application Data
(60) Provisional application No. 61/255,813, filed on Oct. 28, 2009.

(51) Int. Cl. B66D 1/12; G01R 31/34

(52) U.S. Cl. 254/292; 324/765.01

(57) ABSTRACT

Single networkable fault monitoring system for monitoring electrical parameters on at least one electrical phase on at least one interconnected electric chain hoist for various fault conditions. When at least one fault signal is generated, at least one kill signal is generated in the fault monitoring system, causing generation of at least one kill function in at least one chain hoist motor controller. The generated kill function causes a power disconnection to all connected electric chain hoists and/or the entire network of fault monitoring systems. When a fault has been generated, each individual fault signal outputs fault specific diagnostic data from the fault monitoring system to help an operator identify the fault specific electric chain hoist(s) and the specific fault type(s). This data is intended for the purpose of interfacing with an operator monitoring device, LED indicators, data logger, and/or any other user-defined application or combination thereof.

### CROSS-REFERENCE TO RELATED APPLICATION

This application claims the benefit under 35 USC 119 of the filing date of U.S. Provisional Application No. 61/255,813 filed Oct. 28, 2009, the entire content of which is incorporated herein by reference.

### BACKGROUND OF THE INVENTION

1. Field of the Invention

The present invention relates to an improved fault monitoring system for detecting electric chain hoist fault conditions when operating one or more electric, single or poly-phase, electric chain hoists. The fault monitoring system in accordance with the invention is intended for various integration and mounting configurations, including but not limited to: internal connection with a chain hoist motor controller within the controller's enclosure within a separate enclosure and externally connected to a chain hoist motor controller; or any other motor controller, motor control system, or motion control system intended to control at least one electric chain hoist.

2. Description of Prior Art

Electric chain hoists have many different applications and are extensively used in many different industries. Typically, an electric chain hoist comprises of a chain with an attached hook and a single or three-phase motor enclosed within a strong casing containing a reversing contactor, transformer, gearing, and a clutch/brake assembly. The electric chain hoist typically has one or more attachment points connected to the chain and another attachment point directly attached to the enclosed electric chain hoist assembly, in order to suspend loads from it. Commonly, each attachment point consists of a hook. Some examples of these types of electric chain hoists are set forth in detail in U.S. Pat. Nos. 2,991,976, 3,960,362, 4,165,863, and 7,284,743. One common example of a commercially available electric chain hoist extensively used in the entertainment industry is a CM Lodestar Model L one ton, manufactured by Columbus McKinnon Corporation, currently located at 140 John James Audubon Parkway, Amherst, N.Y. 14228-1197. However, it is to be clearly understood that this invention is not limited to any specific electric chain hoist(s). The stated invention is intended for use with any electric chain hoist, or for that matter, any electric motor driven hoist that may include but is not limited to chain hoists, cable winches, hoist trolleys, gantry cranes, or any other type of electric lifting device.

The electric chain hoist typically travels in the up or down direction and is most commonly manually controlled by an operator using one of at least two different methods. The first common method primarily applies when operating an individual electric chain hoist, usually consisting of a pushbutton and/or switching assembly directly connected with a control cable to the individual electric chain hoist and having electricity supplied to the individual electric chain hoist from a separate power source. For example, U.S. Pat. Nos. 4,520,247 and 4,635,903 both represent this type of system. Due to the fact that this type of control is usually reserved for individual electric chain hoist applications, these systems typically do not share the same level of risk associated with applications that require a plurality of electric chain hoists. However, risks still exist. Typically, this type of control system does not incorporate any fault monitoring or fail-safe safety features; however, there still exists potential risk if a fault situation were to arise, possibly leading to a dangerous scenario.

The second common method of manually operated control for electric chain hoists is with a standard chain hoist motor controller, that usually comprises any combination of circuit breakers, power connecters, control connectors, control circuitry, reversing contactors, relays, pushbuttons, switches, control pendants, and/or any other necessary components. This method is the most common method when controlling multiple electric chain hoists. When the standard chain hoist motor controller method is used, typically the power and control signals are supplied to the motor by either separate extension cables or a more permanent hard-wired connection. An example of a portable version of this type of controller is disclosed in U.S. Pat. No. 6,600,289. Operating this type of chain hoist motor controller usually has a much higher inherent risk factor due to the multitude of electric chain hoists that many models are configured to control simultaneously. Also, this type of controller does not include any built-in monitoring or fail-safe safety features.

Use of electric chain hoists is one of the most common methods and practices when moving, lifting, and suspending loads. Electric chain hoists are used throughout many industries and are used frequently in amusement parks, arenas, ballrooms, churches, convention centers, factories, hotels, stadiums, universities, workshops, warehouses, as well as many other commercial, industrial, and public establishments.

Many times when large loads are involved, multiple electric chain hoists are controlled simultaneously by networking multiple chain hoist motor controllers together by means of a control pendant or control station that connects to each individual chain hoist motor controller. The control pendant or control station is then operated by a qualified professional, often being accompanied by a group of qualified observers who simultaneously help watch both the load and the connected electric chain hoists for any signs of abnormal movement, deflections, obstructions, hoist faults, and/or any other possible problematic situation that may occur during the operation of the electric chain hoists.

If a fault situation occurs while an operator is controlling a lift that is using a plurality of electric chain hoists, it can create an extremely dangerous situation. Many of these dangerous situations occur due to the loss of one or more electrical phases, undercurrent, under-voltage, or total power loss from one or more electric chain hoist in the interconnected system while the other electric chain hoists continue to operate normally. If the faulty, stopped electric chain hoist or hoists are not observed immediately and corrective action taken within a short period of time, e.g. a second or two, a catastrophic result can occur. Typically, this will be the direct result of the other connected electric chain hoists continued movement, usually causing dangerous load shifting and overloading often leading to a serious accident that may result in equipment damage, and personal injury or death.

Most chain hoist motor controllers supply live electrical voltage to every connected electric chain hoist in the system, even when the motor controller is in a stand-by state. The standard and relatively safe practice during such a stand-by mode is to have the circuit breakers, contactors, and/or power supply disabled or disconnected until the operator is ready to initiate movement control. Unfortunately, many operators do not follow these procedures or on occasion, they are carelessly overlooked by an operator due to a distraction or other cause, thereby creating a potential for catastrophic situations. Although fairly rare, electric chain hoists have also malfunctioned in such a way to cause a spontaneous self-operation or runaway scenario; lifting or lowering the attached load without any human input. This is obviously an extremely dangerous situation that can cause serious damage to equipment, severe injuries, and/or death. Most chain hoist motor controllers in use today have no way of monitoring for such electric chain hoist malfunctions or a method of stopping them from becoming a problem if they do arise.

Currently, there are a few computerized electric chain hoist control systems that are capable of addressing such problems as well as offering programmable and automated motion control functions. However, the majority of electric chain hoist applications do not require these computerized motion control systems. As such, they are used rarely due to their high cost, inherent complexity, and incompatibility issues associated with most standard electric chain hoists. These computerized motion control systems were designed not only to provide additional safety benefits but primarily to target specialized applications that require extremely dynamic and versatile controllability.

One example of such a computerized motion control system is disclosed in U.S. Pat. No. 4,636,962. This motion control system offers many safety enhancements and other functions. However it is only used in very limited applications, primarily due to the added complexity and costs involved. Another major expense related to such systems and their marketability is that these systems usually either require modification to a standard electric chain hoist or that a more costly sensor integrated electric chain hoist be used, thereby interfacing with the motion control system. Many systems of this type also require a separate computer and/or other necessary components for the safe operation of the electric chain hoists. In addition, extensive operator training is usually necessary due to the complexities of the programming requirements.

Motion control systems such as these are sometimes necessary in the entertainment industry. This typically occurs when a very sophisticated set of theatrical movements is required for a specific show or event. With engineers having designed these motion control systems specifically for only these specialized types of application, they are very rarely used in most other industries and commercial establishments due to their added complexity, expenses, and compatibility issues. The leading majority of the hoisting in the entertainment industry however, only requires and uses standard chain hoist motor controllers and electric chain hoists.

One such prior art system is described in U.S. Pat. Nos. 7,080,824 and 7,080,825. The system uses a position encoder with a position sensor located within the internal components of the electric chain hoist, This is a highly accurate and sophisticated system. However, it is primarily used only when deemed absolutely necessary, this is also due to the impracticality issues.

Another prior art system is disclosed in U.S. Pat. No. 6,209,852, which includes a position encoder mounted externally of the electric chain hoist's body and mounted on a pulley which the chain turns as it moves. The position encoder thereby generates positional data signals. This system is even less accurate than the previously mentioned due to its external configuration and the possibility of an improper installation. This system is complex costly, requires additional equipment and highly trained operators thereby preventing widespread use.

### SUMMARY OF THE INVENTION

An embodiment of the present invention provides an electric chain hoist fault monitoring system that is integrated within a chain hoist motor controller, interconnected in conjunction with a separate chain hoist motor controller, and/or any networked combination of the stated two types of chain hoist motor controllers.

The fault monitoring system monitors each phase individually on each individual interconnected single or poly-phase electric chain hoist for specific predefined electrical parameters. The fault monitoring system may also be configured to incorporate load cell feedback for generating load fault signals when they occur. If a fault condition is detected, a specific condition or electric chain hoist associated fault signal is thereby generated. The fault signal is designed to switch a relay, that in turn generates a kill signal generating a power disconnect to all interconnected electric chain hoists in the system. The system can be either a single chain hoist motor controller or a networked array of two or more chain hoist motor controllers.

The invention therefore addresses the extremely dangerous situations that can potentially occur, when specific fault situations arise, in a single electric chain hoist or any plurality of electric chain hoists while controlling a heavy load, especially when multitudes of electric chain hoists and networked chain hoist motor controllers are involved. The invention thus eliminates the very high potential for equipment damage, injuries to people, or even death when such equipment failures take place, which fault situations are usually due to equipment failure, power or control cable problems, and/or any number of other problems.

Indeed, the invention is designed and tested to address such fault situations, automatically disconnecting the source power being supplied to all of the interconnected electric chain hoists in the single or networked array of chain hoist motor controllers. When a fault signal is generated there is also a condition and electric chain hoist specific signal output designed specifically to interface with monitoring devices, data loggers, or other user-defined applications to help diagnose the cause of the fault event. This said fault monitoring system also does not require any modification of existing chain hoist motor controllers, cables, and/or electric chain hoists; thus intrinsically increasing exponentially the safety factor involved when running single or multiple motor driven electric chain hoists supporting a load or loads without the need of any additional specialized equipment.

Another possible problem encountered with electric chain hoists is when a malfunction occurs and the electric chain hoist starts traveling either up or down without an operator's command. Although this is an infrequent occurrence, it happens from time to time and has resulted in a very problematic or near catastrophic situation. In the event that an unselected electric chain hoist runs, the stated electric chain hoist fault monitoring system will detect the movement as a not-commanded electrical current, thereby being a specific fault condition and immediately proceed to disconnect the power to all of the electric chain hoists connected to the system, whether as a stand-alone or a networked array of two or more chain hoist motor controllers.

The invention is also suited for particular application in the entertainment industry that uses large numbers of electric chain hoists to suspend large trussing grids and other structures that often require a plurality of electric chain hoists for these synchronized lifts. Professionals in the field are familiar with such occurrences and many have seen accidents death as a result. The majority of the loads requiring electric chain hoists in the entertainment industry require simple hoisting and suspension only, without the need for more complex, programmable functions and the associated costs inherent in most computerized encoder systems.

It is also a fairly common practice to use rental electric chain hoists for many travelling shows due to the huge expenses and time constraints involved when shipping long distances. Encoder systems traditionally require some extent of electric chain hoist modification or specialty encoder integrated electric chain hoists, which usually are not readily available from most equipment rental businesses. For this reason, these systems are so rarely used. On the other hand, the invention overcomes such obstacles and helps create a safer environment industry-wide.

With the proper use of this electric chain hoist fault monitoring system in accordance with the stated invention, many of these potentially dangerous and costly fault situations will be avoided and/or if unavoidable, will be corrected in a simple and easy to use manner. This fault mitigation is accomplished in a non-invasive way that is low cost and compatible with most electric chain hoists and related equipment in the United States market. This invention is an improvement in all of these stated areas and more importantly a viable solution to current safety problems, in a practical, cost effective, and market friendly package.

This improved fault monitoring system is intended for various integration and mounting configurations including, but not limited to: internal connection with a chain hoist motor controller within the chain hoist motor controller's enclosure; within a separate enclosure and externally connected to a chain hoist motor controller with at least one connected electric chain hoist; as any networked combination of the previously hoist motor controller with at least one connected electric chain hoist; as any networked combination of the previously stated two; or any other combination of at least one electric chain hoist, at least one chain hoist motor controller, and/or any other device or devices connected to at least one electric chain hoist.

### BRIEF DESCRIPTION OF THE DRAWINGS

The invention may best be understood by reference to the following detailed description of and illustrative embodiment when read in conjunction with the accompanying drawings, wherein:

FIG. 1 is a block diagram of a four Channel Improved Portable Chain Hoist Motor Controller with Integrated Fault Monitoring System which supplies three-phase alternating current power, directional control, and fault monitoring to four electric three-phase chain hoists according to the invention, which block diagram is also applicable to portable chain hoist motor controllers with other than four channels, e.g., to those with two channels, six channels and eight channels;

FIG. 2 is a block diagram and flow chart showing power and data path flow of the components further associated with FIG. 1;

FIG. 3 illustrates a flow chart of the GO command signal processing for the fault logic circuitry;

FIG. 4 illustrates a flow chart of the UP/DOWN Motor Select command signal processing for the fault logic circuitry;

FIG. 5 illustrates a flow chart of the Current Sensor Array signal processing for the fault logic circuitry;

FIG. 6 illustrates a flow chart of the SET/RESET KILL command signal processing for the fault logic circuitry;

FIG. 7 illustrates a flow chart of the signal processing for the Fault Logic circuitry when a motor fails to run on GO command;

FIG. 8 illustrates a flow chart of the signal processing for the Fault Logic circuitry when a motor fails to turn off;

FIG. 9 illustrates a flow chart of the signal processing for the Fault Logic circuitry for conditional faults;

FIG. 10 illustrates a flow chart of the signal processing for the Fault Logic circuitry for Anomalous Current Faults;

FIG. 11 is a truth table of faults according to the invention;

FIG. 12 is a flow chart of the Standard Operating Procedures associated with the preferred embodiment of the invention;

FIG. 13 is a flow chart of the Initial Operator Procedure for the preferred embodiment of the invention; and

FIG. 14 is a flow chart showing fault troubleshooting in accordance with the invention.

### DETAILED DESCRIPTION OF THE INVENTION

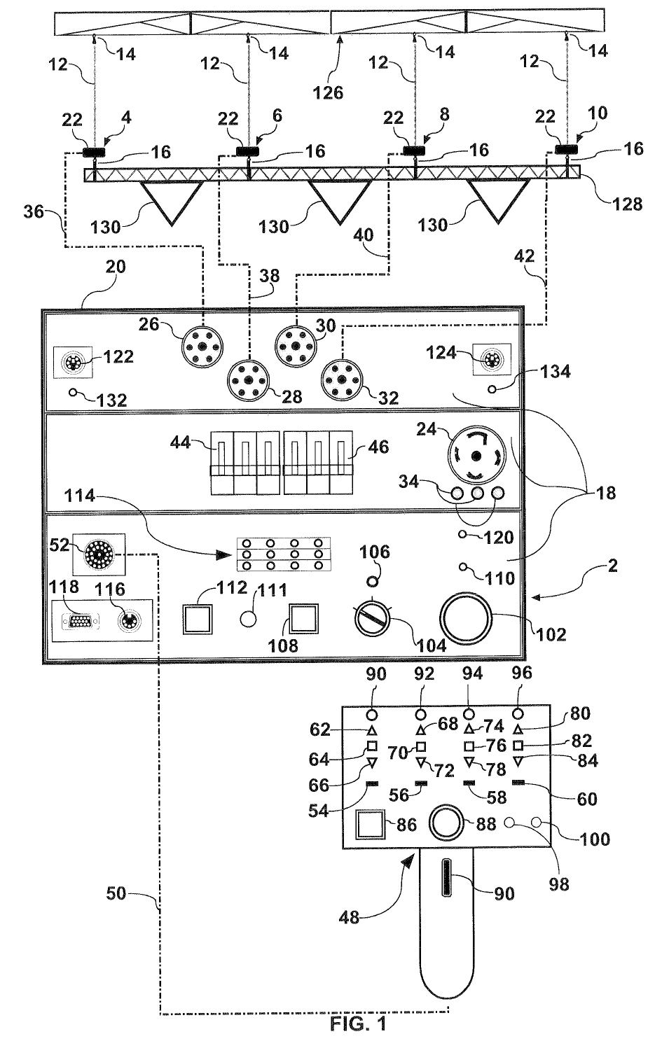

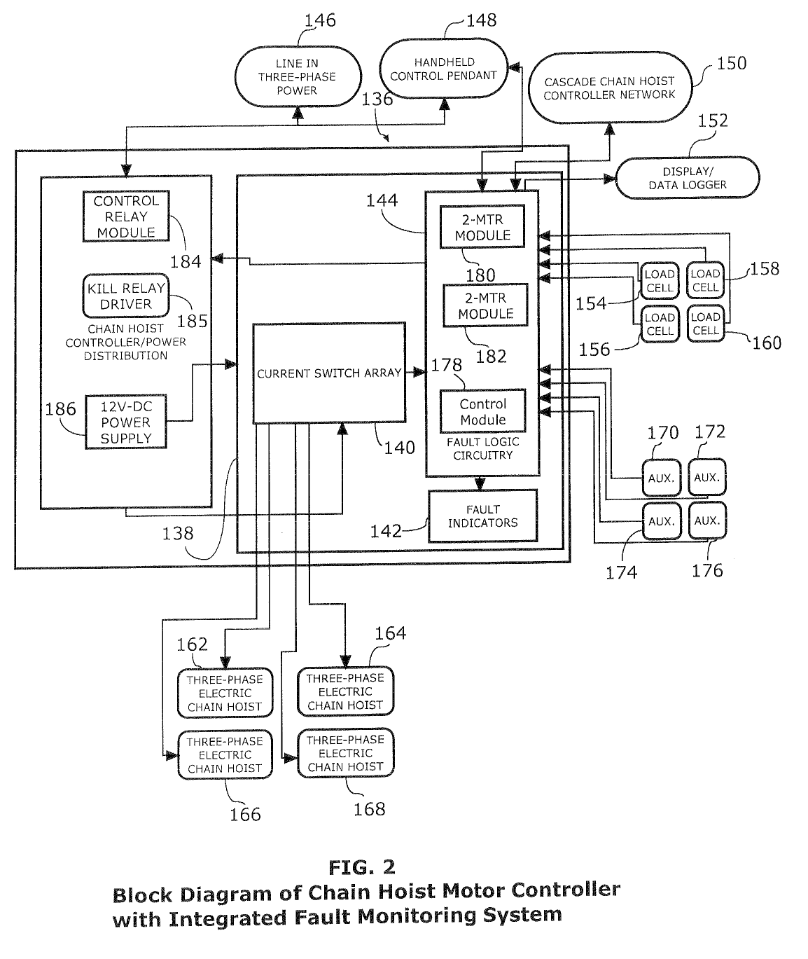

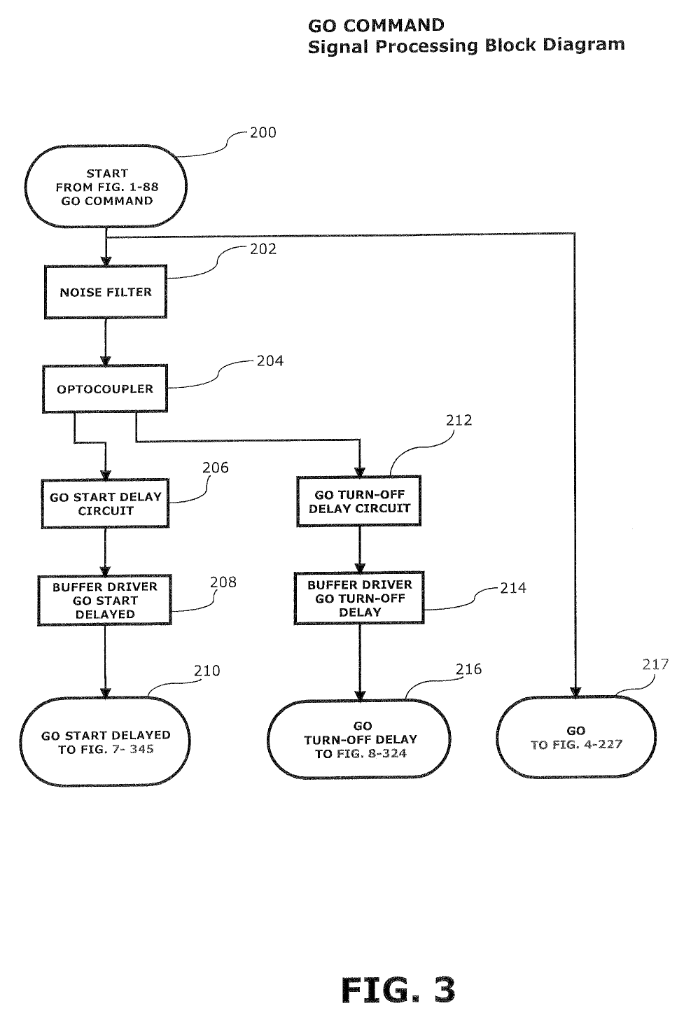

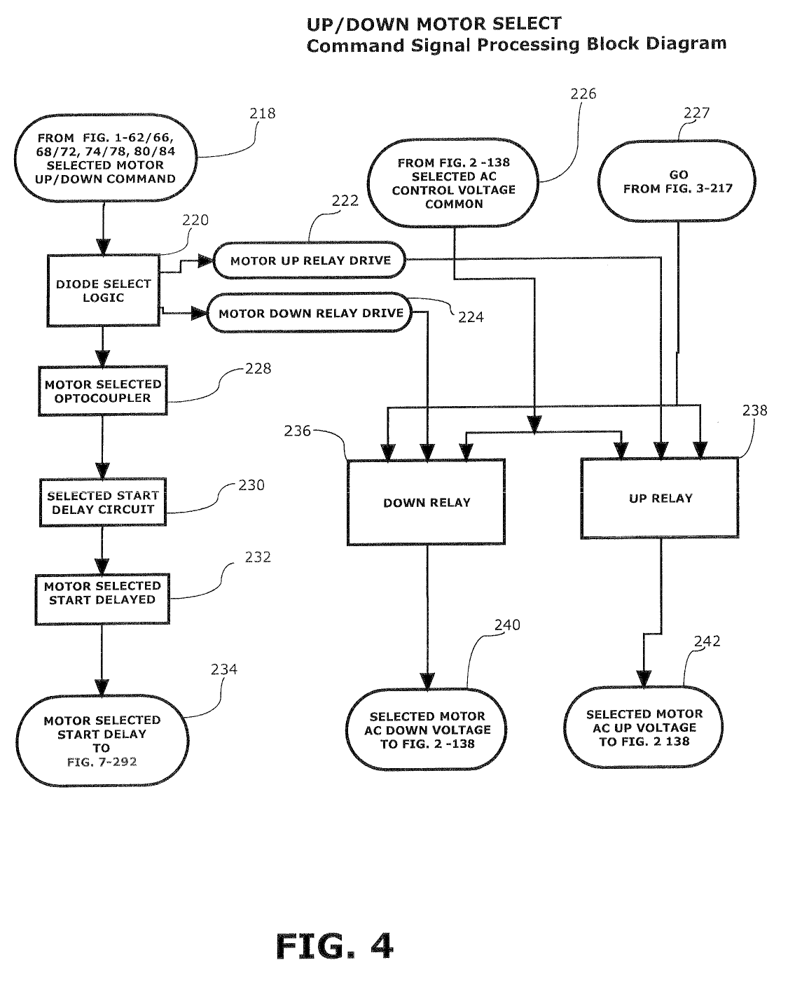

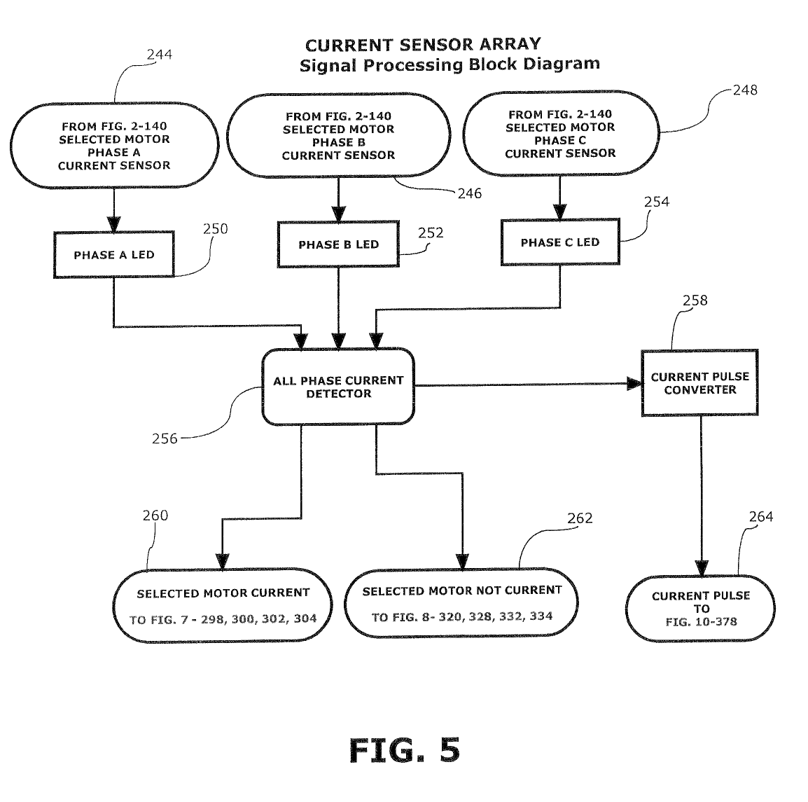

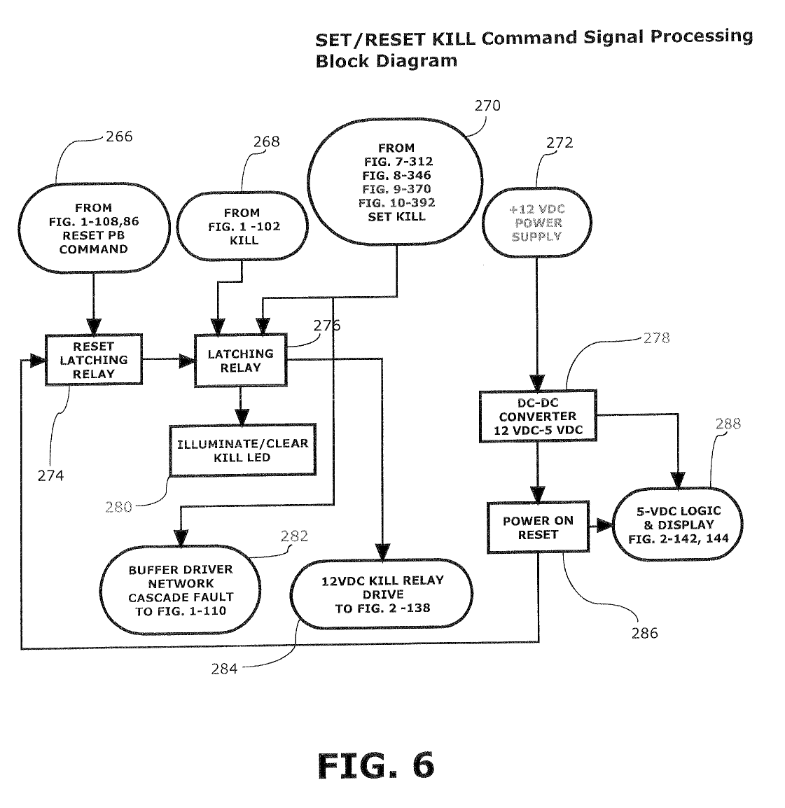

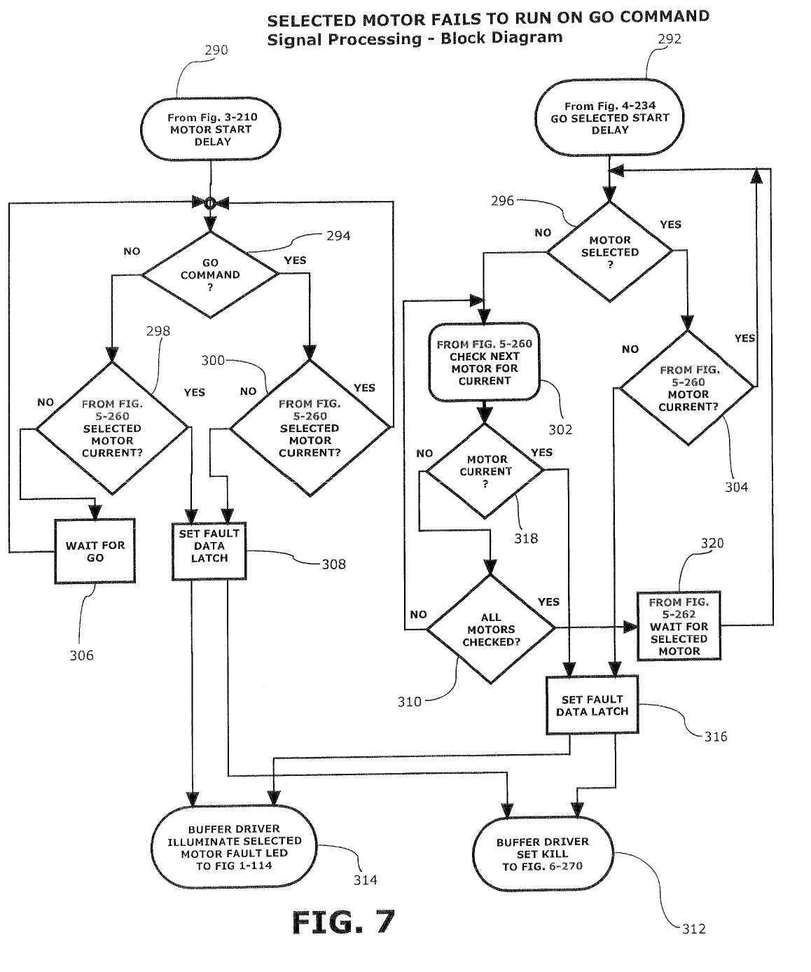

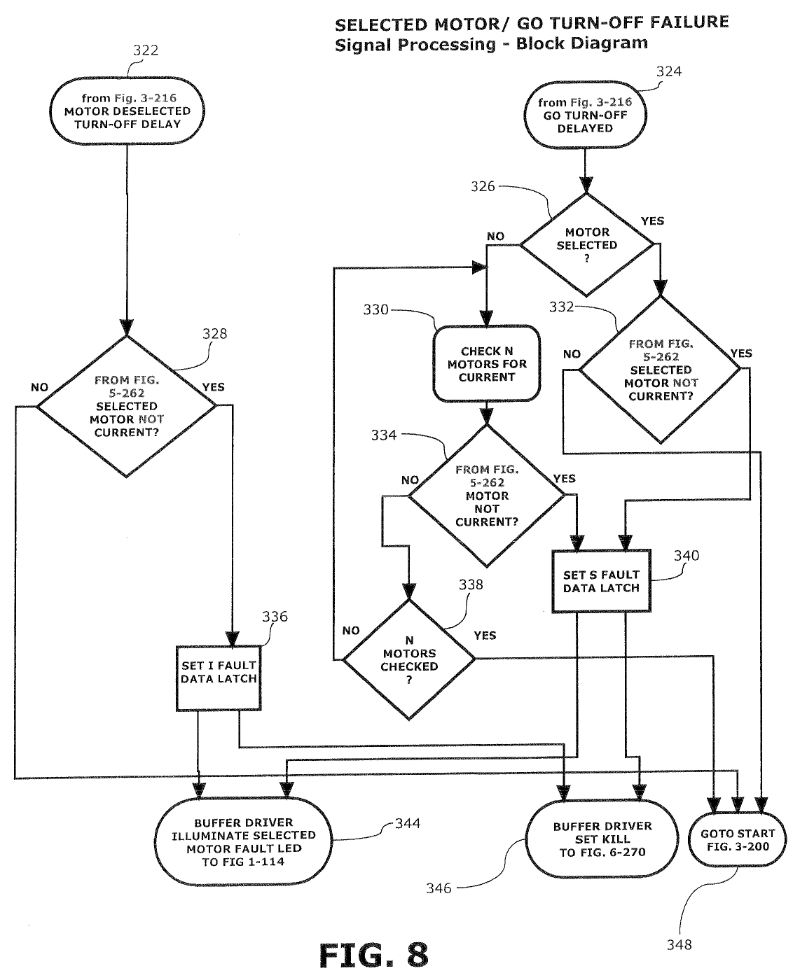

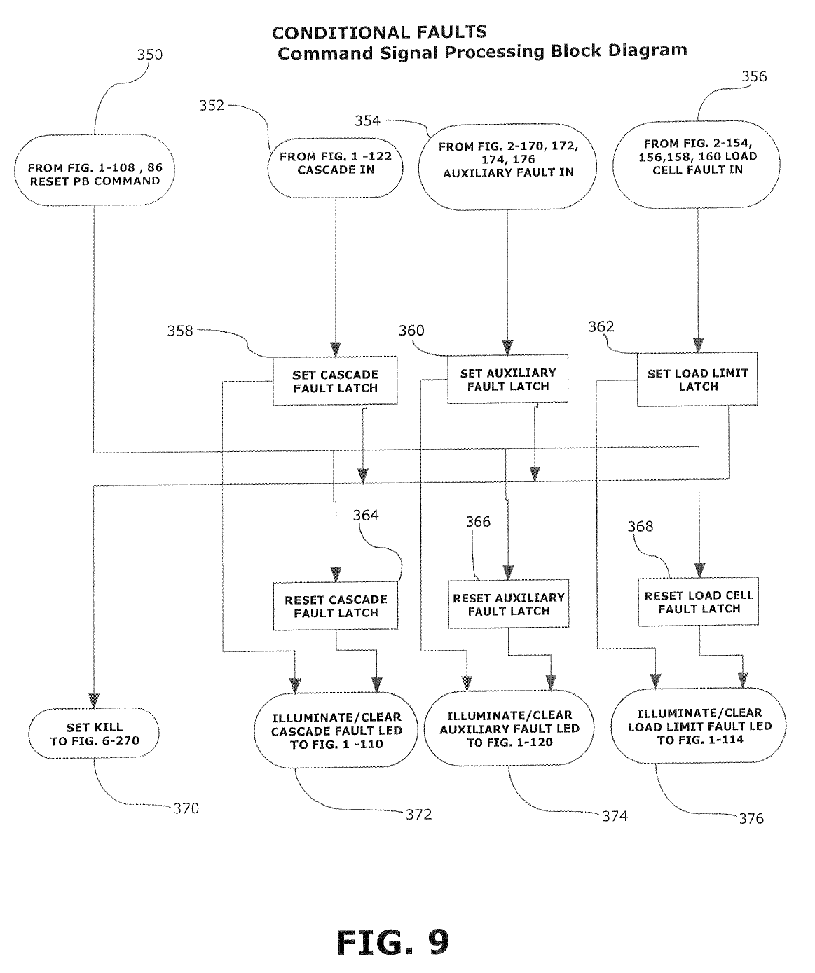

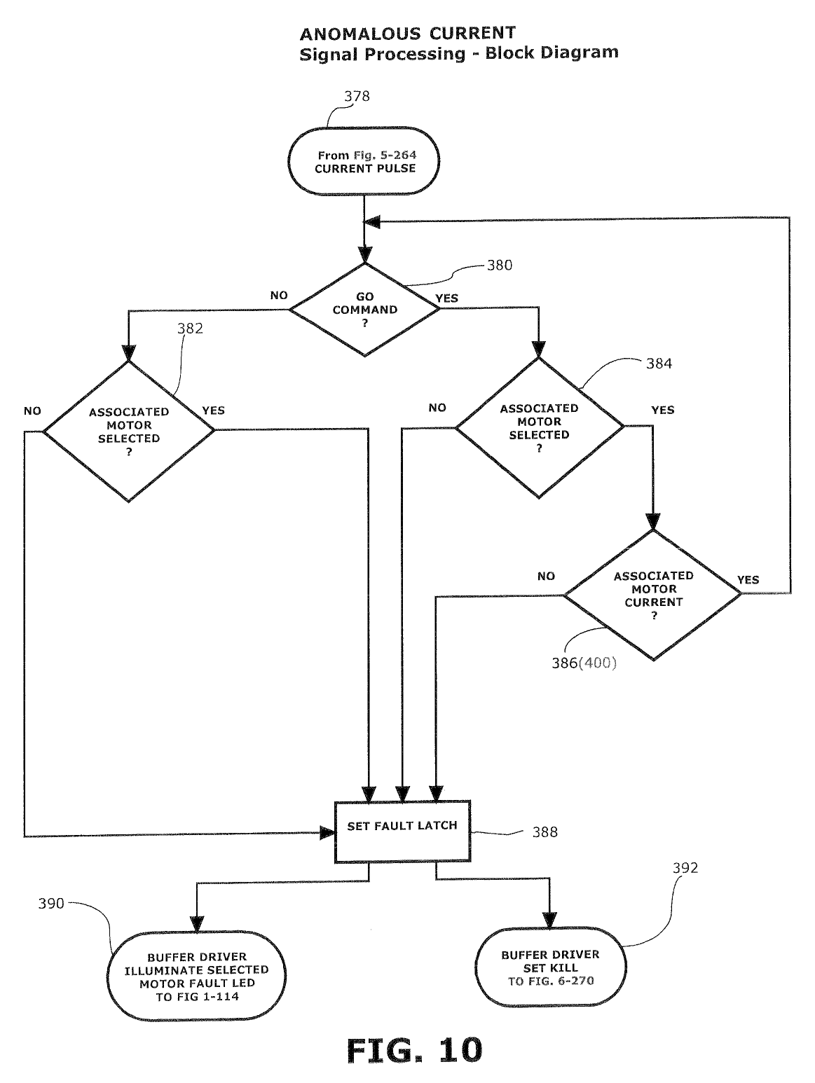

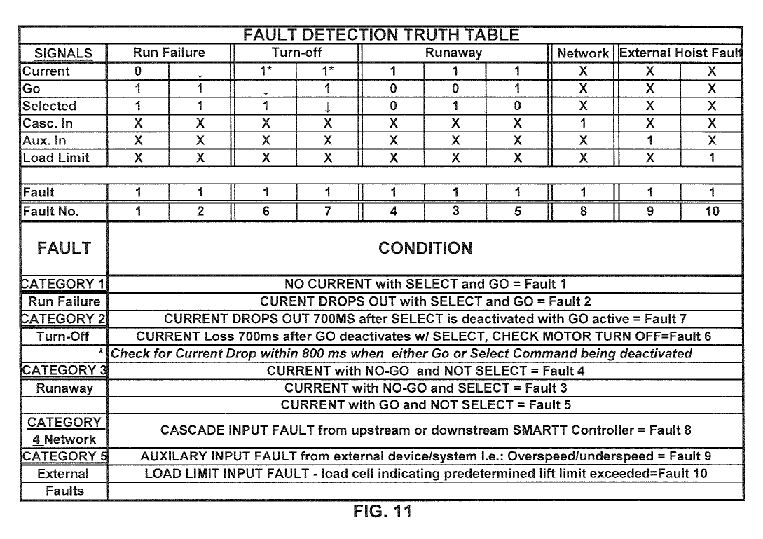

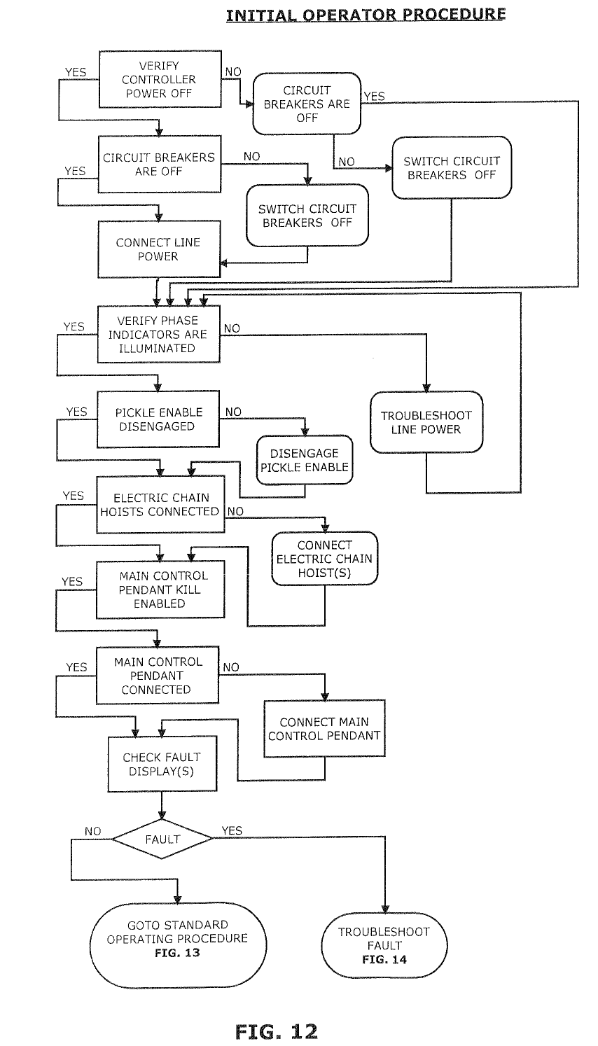

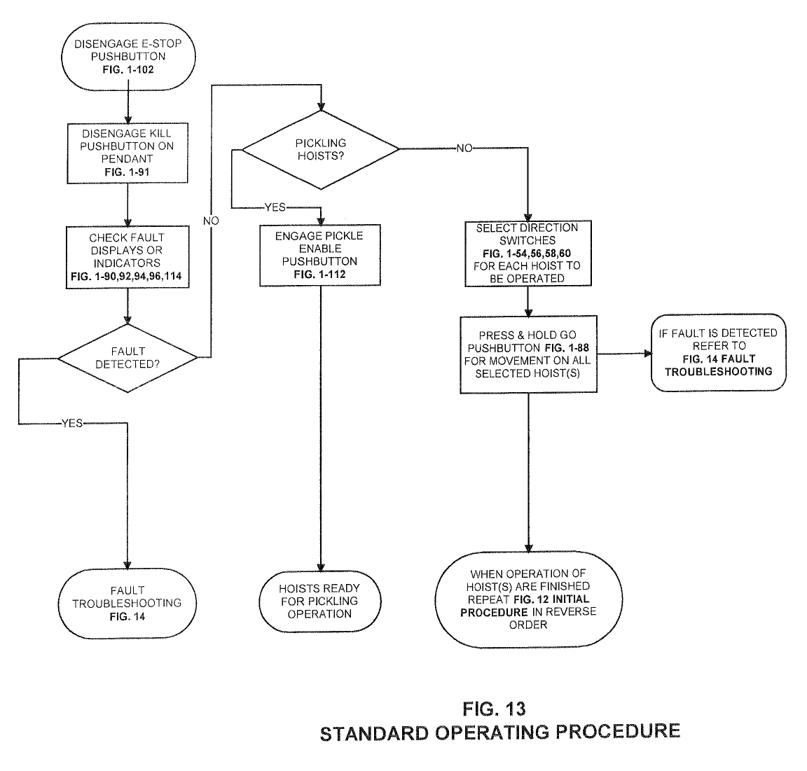

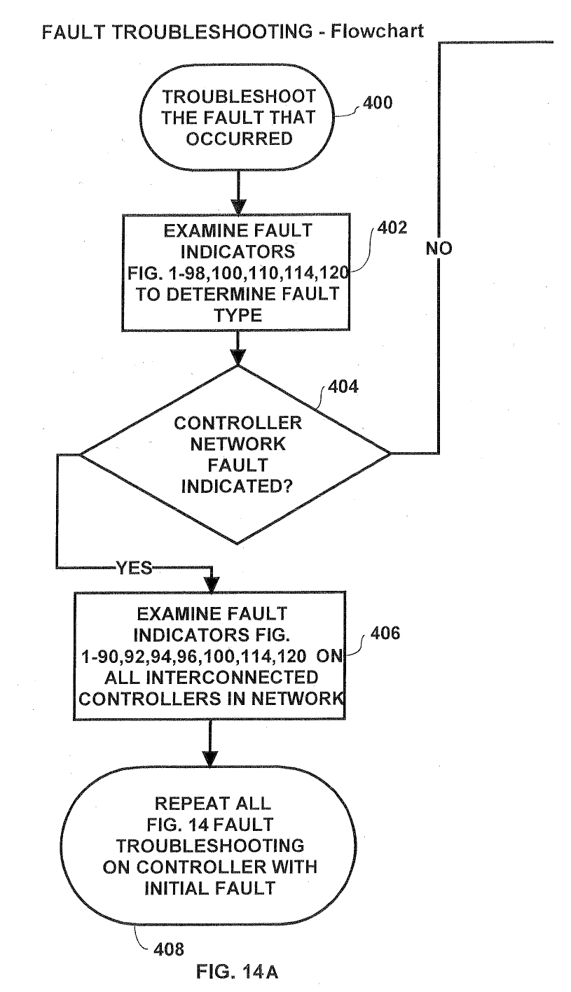

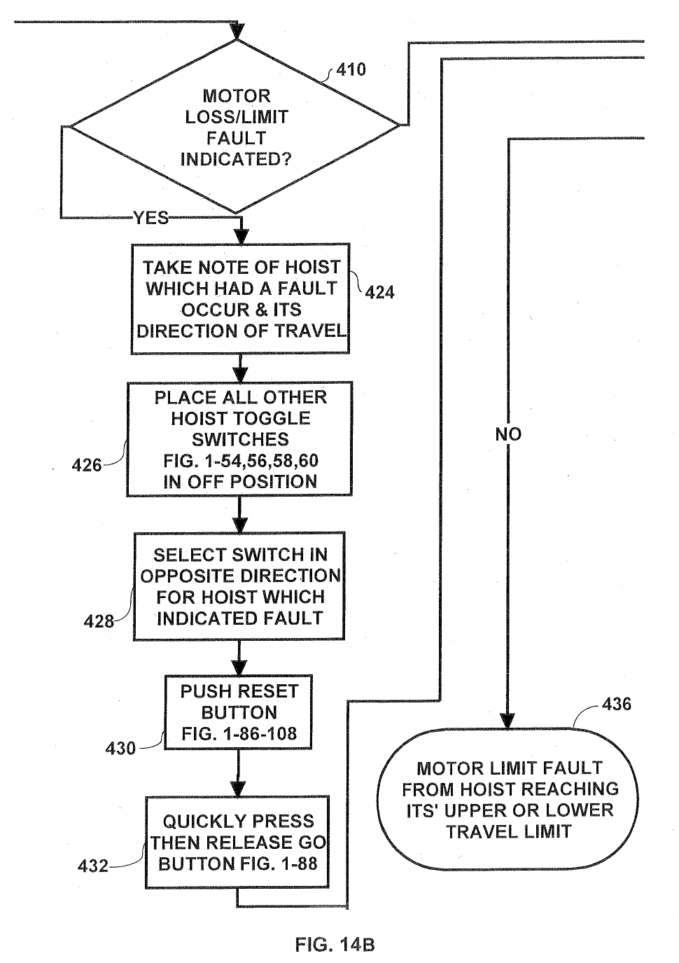

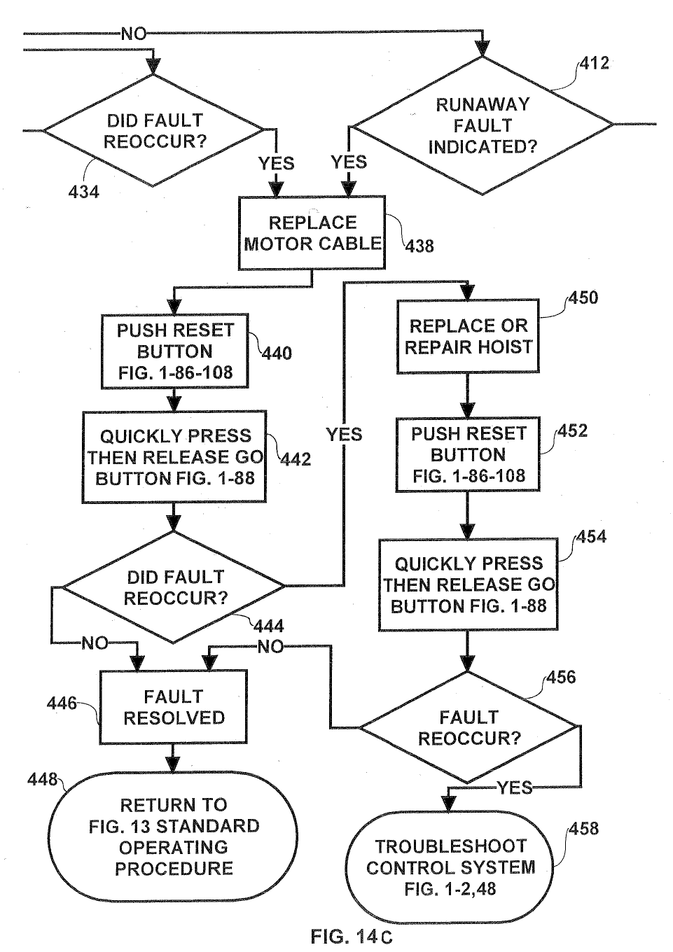

Referring to the accompanying drawings wherein the same reference numbers refer to the same or similar elements, FIG. 1 illustrates in combination a 4 Channel Improved Portable Chain Hoist Motor Controller with Integrated Fault Monitoring System 2 as a preferred embodiment of the invention. The combination provides four electric three-phase chain hoists 4, 6, 8, and 10 with three-phase alternating current power, coordinated control, and fault monitoring protection. Each electric chain hoist 4, 6, 8, and 10 may be of any type or modification including but not limited to single phase, poly-phase, single speed, multi-speed, variable frequency drive, or any other possible combination or variation thereof. For example, the electric chain hoists 4, 6, 8, and 10 may be CM Lodestar Model L chain hoists manufactured by Columbus McKinnon Corporation, currently located at 140 John James Audubon Pkwy., Amherst, N.Y., 14228-1197. However, it is to be clearly understood that this invention is intended to be configurable to any electrically motor driven chain hoist or hoists regardless of manufacturer, model, capacity, additional functionality, or any other difference.

The electric chain hoists 4, 6, 8, and 10 each comprise a chain 12 with an attached hook 14 and a three-phase motor 22 enclosed within a strong casing containing, for example, a reversing contactor, transformer, gearing, and a clutch/brake assembly (internal hoist components not visible). The electric chain hoists 4, 6, 8, and 10 each have one attachment point connected to the chain and another attachment point directly attached to the enclosed electric chain hoist assembly 16, in order to suspend loads from it. Attachment points of the electric chain hoists 4, 6, 8, 10 are thus elements 14 and 16. The electric chain hoists 4, 6, 8, and 10 all attach to a main structural truss 126 which represents a load bearing component of a building's structure rated for up to, for example, 4,000 lbs of additional vertical load (weight) at each attachment point 14. The electric chain hoists 4, 6, 8, and 10 are attached to, for example, a 40′×12″×12″ aluminum truss structure 128 which is supporting a load of three individual 1000 pound fixtures 130.

The four Channel Improved Portable Chain Hoist Motor Controller with Integrated Fault Monitoring System 2 comprises electrical and electronic components housed in a NEMA (National Electrical Manufacturers Association) enclosure mounted within a casing or housing such as a sturdy road case 20 with a removable lid (not shown), and that as those typically housing most chain hoist motor controllers used in the entertainment industry. The top panels of the NEMA enclosure are typically 19 inch rack mountable, functioning as the control, socket, and display top panels 18 for the portable Chain Hoist Motor Controller with Integrated Fault Monitoring System 2. The top panels 18 include, for example, at least one three-phase power input (male) socket to provide the primary power supply, three separate neon phase indicators 34, and four separate 7-pin output sockets 26, 28, 30, and 32 for supplying the electric chain hoists 4, 6, 8, and 10 with three-phase power and directional control when coupled with the seven conductor motor cables 36, 38, 40, and 42. Instead of three separate neon-phase indicators, other types of indicators may be used in the invention.

The four electric three-phase chain hoists 4, 6, 8, and 10 are connected to the Chain Hoist Motor Controller with Integrated Fault Monitoring System 2 with the four separate seven conductor motor cables 36, 38, 40, and 42 to supply the three-phase power and directional control for each chain hoist 4, 6, 8, and 10. The four separate 7-pin output sockets 26, 28, 30, and 32 may be coupled to the two separate three pole 10-Amp circuit breakers 44 and 46 in pairs, with the 7-pin output sockets 26 and 28 coupled to the CH 1-2 circuit breaker 44 and the 7-pin output sockets 30 and 32 coupled to the circuit breaker 46.

Operator control is primarily provided to the electric chain hoists 4, 6, 8, and 10 through the control pendant 48 which is coupled to the Chain Hoist Motor Controller with Integrated Fault Monitoring System 2 through a control cable, for example, a 26-conductor control cable 50, that is connected to the pendant input socket 52. Three-position SPDT toggle switches 54, 56, 58, and 60 (also referred to herein as Motor Up/Off/Down Switches) on the main control pendant 48 enable the operator to select either up or down directional control for each individual electric chain hoist 4, 6, 8, and 10. Selecting up, off, or down on each three-position SPDT toggle switch 54, 56, 58, and 60 corresponds to a specific triangle LED indicator (up or down) 62, 66, 68, 72, 74, 78, 80, and 84 or square LED indicator (off) 64, 70, 76, and 82 depending on, for example, the direction for the particular chain hoist selected. Instead of triangle LED indicators or Square LED indicators, other types (including different shapes) of indicators may be used in the invention.

The control pendant 48 also incorporates a momentary SPDT GO switch or pushbutton 88, a latching SPDT KILL pushbutton 91, and a momentary SPDT RESET pushbutton 86 that enable the associated specific function on the portable Chain Hoist Motor Controller with Integrated Fault Monitoring System 2. The control pendant 48 also includes chain hoist specific fault indicating LED's 90, 92, 94, and 96, or other types of indicators, that turn on or are otherwise actuated when any chain hoist specific fault is encountered, as well as a controller network fault LED indicator 98 and an auxiliary fault LED indicator 100 that are included for system wide fault indicating. Other types of indicators may be used that are turned on or otherwise actuated for system wide fault indicating.

Each individual electric chain hoist 4, 6, 8, and 10 can be controlled by a pickle or pendant type of control (not shown) that connects to any individual electric chain hoist, an example of this type of pickle control can be referenced in its entirety in U.S. Pat. No. 4,520,247 invented by James J. Pancook and Otmar M. Ulbing both of NY and assigned to Columbus McKinnon Corporation, Amherst, N.Y. This pickle type of control is primarily used in the entertainment industry only when initially making the chain hoist connection/disconnection to the load or running the chain out to its' lower limit. A DPDT pickle enable latching pushbutton 112 on the portable Chain Hoist Motor Controller with Integrated Fault Monitoring System 2 provides voltage when depressed or engaged to the connected electric chain hoists 4, 6, 8, and 10. This operation overrides the fault monitoring circuitry and allows for individual electric chain hoist pickling or control. When this pickle enable latching pushbutton 112 is enabled, a “Fault System Override!” warning LED indicator 111 illuminates to warn the operator that the fault system is off, this also removes all power from the main control pendant 48. Instead of a latching pushbutton 112, another type of switch may be used in the invention. Instead of warning LED indicator 111, another type of indicator may be used in the invention.

The portable Chain Hoist Motor Controller with Integrated Fault Monitoring System 2 also provides a SP3T phase selector switch 104 to allow an operator switching capability between automatic or manual forward and reverse phase selection. When this phase selector switch 104 is in the automatic position, the phase rotation sensing circuitry (not illustrated) detects out-of phase rotation on the incoming power and switches load phasing from forward contactor to reverse contactor switching the load phasing. Therefore this automatic phase circuitry always supplies the correct phasing to the electric chain hoists 4, 6, 8, and 10 via the four separate seven conductor motor cables 36, 38, 40, and 42. When in automatic mode, a green LED indicator 106 illuminates to notify the operator of the correct phase sequence. Instead of indicator 106, another type of indicator, whether visual, audible, etc., may be used in the invention.

Controller network in socket 122 and controller network out socket 124 provides controller cascading capability enabling multiple controllers to be networked providing Cascading Chain Hoist Control Network 150, see FIG. 2, of any configuration specified in the current invention. When a positive connection is present on the controller network in socket 122, the green LED indicator 132 latches on and when a positive connection is present on the controller network out socket 124, the green LED indicator 134 latches on. Instead of green LED indicators 132 and 134, another type of indicator, e.g., a different visual indicator, may be used in the invention.

In the event that an incoming fault signal is detected on either the controller network in socket 122 or the controller network out socket 124, a controller network fault is generated on the Chain Hoist Motor Controller with Integrated Fault Monitoring System 138 thereby latching the controller network fault LED 110 generating a Kill function that removes power from all the electric chain hoists 4, 6, 8, and 10. An Emergency Stop DPDT latching pushbutton 102 enables a Kill function that removes power from all the electric chain hoists 4, 6, 8, and 10. This also sends a kill signal out of the controller network out socket 124, which, if attached to another chain hoist motor controller with fault monitoring system(s) (not currently illustrated) via the Cascade Chain Hoist Control Network 150 of any configuration specified in the current invention, generates a controller network fault on any interconnected network controller generating a Kill function that removes power from all networked electric chain hoist.

The load cell socket 118 allows four separate load cells 154, 156, 158, and 160 (see FIG. 2) to be connected and they are designed to correspond numerically to each electric chain hoists referring back to FIG. 1, i.e., chain hoists 4, 6, 8, and 10 connected to the system. The auxiliary socket 116 allows the user to connect any Auxiliary Sensor 170, 172, 174, and 176 (see FIG. 2) to the Chain Hoist Motor Controller with Integrated Fault Monitoring System 2 that generates a compatible fault signal. Upon an incoming auxiliary fault signal, the auxiliary fault LED indicator 120 latches on to notify the operator of the fault condition and generates a Kill function that removes power from all the electric chain hoists 4, 6, 8, and 10 and sends a network controller fault all networked controllers. Instead of auxiliary fault LED indicator 120, another type of indicator may be used in the invention.

When any motor specific fault is generated the corresponding fault type and electric chain hoist specific LED on the chain hoist fault indicator panel 114 illuminates. The SPDT Reset pushbuttons 86 and 108 supply a reset signal that unlatches all of the red fault LED's, resets the fault kill dual coil relay (kill relay driver 185 see FIG. 2) and also sends a reset signal to both the controller network in socket 122 and controller network out socket 124. Network In LED 132 and Network Out LED 134 indicate connections to upstream and downstream Improved Portable Chain Hoist Motor Controllers, respectively.

The Fault Logic Circuitry is preferably an event driven logic circuit that monitors the GO switch or pushbutton 88, all Motor Select three-position SPDT toggle switches 54, 56, 58, and 60 and the Current Switch Array 140 for any changes in status. All monitored statuses have predetermined operational characteristics, some that result in one of eight unique fault conditions for each motor.

FIGS. 2-10 are illustrative flowcharts of the Fault Logic Circuitry as illustrated in Integrated Fault Monitoring Block Diagram 136, see FIG. 2. The Fault Logic Circuitry 144 is a major component of the Integrated Fault Monitoring System 138. For the sake of brevity, this description will only address the fault logic circuitry for one motor. The same circuit and logic may be utilized for any number of motors that the controller is designed to monitor. The Fault Logic Circuitry 144 may be activated by placing circuit breaker 44 to the “on” position supplying line in three phase power 146 activating the 12-Volt DC Power Supply 186 providing 12-volts DC to the Control Relay Module 184, see FIG. 2, generating a 0.5 second Power On Reset 286, see FIG. 6, to clear any anomalous power-on faults. The DC-DC Converter 278, see FIG. 6, located on the Control Module 178, see FIG. 2, provides 5-Volt DC power for all of the logic utilized on the Control Module 178, 2-Motor Fault Modules 180, 182, Fault Indicators 142, Controller Network Fault LED 110, and Auxiliary Fault LED 120. Activating the Pickle Enable Switch 111 disconnects the 12-Volt DC supply voltage to the 12-Volt DC-DC Converter 278, see FIG. 6), turning off the +5 VDC disabling the Fault Logic Circuitry 144. The Hand-held Control Pendant 148 provides all commands via the Chain Hoist Controller/Power Distribution block consisting of Control Relay Module 184 and Kill Relay Driver 185.

The Fault Logic Circuitry 144 is preferably wired in a one-to-one relationship. That is, all of the circuits and components for each Electric Chain Hoist are repeated for each Electric Chain Hoist and are in an array. For example, Electric Chain Hoist 4 has its own Current Sensor Array consisting of 3 each phase sensors 162, 164, 166, 168. Electric Chain Hoist 6 has its own Current Array of 3 each phase sensors, etc. This architecture is preferably employed for all fault logic circuits. The Fault Logic Circuitry 144 additionally monitors Load Cells 154, 156, 158, 160 and has Auxiliary inputs 170, 172, 174, and 176 for user specified special fault conditioning monitoring equipment. Cascade Hoist Controller Network 150 provides the capability of daisy chaining upstream and downstream similar units. The display Data Logger 152 provides the capability to record events as they happen.

Upon power turn-on, the Fault Logic Circuitry 144 proactively monitors the status of Current Sensor Array 140 for anomalous current, the status of the GO switch or pushbutton 88, and all Motor Up/Down/Off Select Switches 54, 56, 58, 60. Fault Logic Circuitry 144 thus constitutes part of a fault monitoring unit of the fault monitoring system in the invention, that monitors the current sensors associated with the electric chain hoists 4, 6, 8, and 10. The Selected Motor Phase A, B, C Current Sensors 244, 246, 248 in the Current Sensor Array 140 are hardwired to monitor each phase of the associated motor output socket 26, 28, 30, 32 and sent to the 2-Motor Fault Modules 180, 182 (see FIG. 5). With further reference to FIG. 5, phase LED indicators 250, 252, 254 are illuminated on the 2-Motor Fault Modules 180, 182 to provide visual status of motor power. The All Phase Current Detector 256 processes the current signals providing the current status to Selected Motor Current 260 and Selected Motor Not Current 262, and enables the Current Pulse Converter 258 to send a Current Pulse via 264, to 378 verify the GO command 380 (see FIGS. 5 and 10). If the GO Command 380 is true, the Associated Selected Motor 384 instantly checks to see if there are Selected Motors and if they are associated with the Associated Current 386. If the Associated Motor Selected is not in a one-to-one relationship with the current detected, a Set Fault Latch 388 is immediately generated and the appropriate Buffer Driver 390 illuminates the appropriate Fault LED (see FIG. 10). Buffer Driver 392 sends a Set KILL to the Latching Relay 276 interrupting the 12 VDC Kill Enable turning off the Kill Relay thereby interrupting Motor AC Power (see FIGS. 6 and 10).

Referring back to FIG. 10, if the Go Command 380 is false, the Associated Motor Selected circuitry checks the status of Associated Motor Selected 382 to determine the appropriate fault, and immediately setting Fault Latch 388, causing Buffer Driver 390 to illuminates the appropriate Fault LED and Buffer Driver 392 to send a Set Kill to the Latching Relay 276 interrupting the 12 VDC Kill Relay Drive 284 turning off the Kill Relay interrupting Motor AC Power (see also FIG. 6). If there is a one-to-one correspondence, the Fault Logic Circuitry 144 continues to monitor for status changes via the logic loop consisting of Go Command 380, Associated Motor Selected 384 and Associated Motor Current 386 (see FIGS. 2 and 10). The Kill signal is preferably a 12 VDC drive provided by the Enable Switch 102 to activate the Kill Relay. The 12 VDC Kill passes through the normally closed position of The Latching Relay 276 when it is in the reset position and is used by the Fault Logic Circuitry to enable/disable the line power distribution to the motors (see FIG. 6).

Referring still to FIG. 6, the Fault Logic Circuitry 144 is reset by a Power On Reset 286 that generates a 0.5 second ground going pulse to the reset coil of the Latching Relay 274 and all fault latches or by the Reset pushbuttons 86, 108 that generates a manual reset.

Referring now to FIG. 3, GO switch or pushbutton 88 initiates positive 12 VDC Go Command, 200, 217 passes through a Noise Filter 202 to minimize switch noise activating Optocoupler 204 and provides the 12 VDC drive for the relay 236, 238. The Optocoupler 204 is preferably a Smith Trigger device with a tri-state output that produces a logical 1 output. The positive going edge of the Optocoupler 204 triggers a retriggerable monostable multivibrator setting a Go Start Delay Circuit 206. The Go Start Delay Circuit 206 delays the Go signal by approximately 50+/−5 ms to allow time for motor start-up. To meet fan-out requirements, the Go Start Delay signal is sent to a Buffer Driver Go Start Delayed 208 and distributed by Go Start Delayed 210. When the GO switch or pushbutton 88 is deactivated returning the 12 VDC Go Command 200 to ground, the trailing negative edge triggers a retriggerable monostable multivibrator setting a Go Turn-Off Delay Circuit. The Turn-Off Delay Circuit delays the turn-off approximately 175+/−17 ms before checking the current array to allow time for the motors to stop. To further meet fan-out requirements, the Go Turn-Off Delay 212 signal is preferably sent to a Buffer Driver Go Turn-off Delay 214 and distributed by Go Turn-off Delay 216.

Referring back to FIG. 1 and now to FIG. 4, the Motor Select three-position SPDT toggle switches 54, 56, 58, 60 when set to the up/down position generate an approximately +12 VDC return to the Selected Motor UP/Down Command 218 for the appropriate Diode Select Logic 220. The position of each switch is sent to its own Motor Up Relay Drive 222 or Motor Down Relay Drive 224 and if GO switch or pushbutton 88 is active, it sends +12 VDC to Go 232 enabling the Diode Select Logic to enable Selected AC Control Voltage Common 226 to be switched by the Down Relay 236 to apply control voltage to Selected Motor AC Down Voltage 240 or Up Relay 238 to apply control voltage to Selected Motor AC Up Voltage 242 activating the control up/down contactor in the selected motor(s). The Diode Select Logic also sends a motor selected ground going signal to associated Motor Selected Optocoupler 228 generating a positive going output Motor Selected signal to enable the Fault Logic Circuitry 144, Selected Start Delay Circuit 230 containing a retriggerable monostable multivibrator to start timing a Motor Selected Start Delayed 232. An approximately 50+/−5 ms Motor Selected Start Delay 234 is sent to the Motor Start Delay 292 to allow time for the AC Motor to start running providing current feedback.

FIG. 7 is a flowchart showing the fault detection logic if a Selected Motor Fails To Run On Go Command and also checks for a non-selected motor running. Running a motor is initiated in one of at least two ways: the first being a combination of setting one or more of the UP/Off/Down Switches to either the UP or Down position generating a Motor Selected Start Delay 292 (see box 234 in FIG. 4 for details) and then the GO switch or pushbutton 88 being activated (see FIG. 1) creating a motor Go Start Delay 290 (see box 234 in FIG. 3 for details); and the second method is the GO switch or pushbutton 88 being active (see FIG. 1) creating a motor Go Start Delay 290 and switching one or more of the UP/Off/Down Switches to either the Up or Down position generating a Motor Selected Start Delay 292 (see, again, FIG. 3). In simple terms, in order for a motor to run, it needs a directional command UP/Down and a Go Command concurrently. If either command is deactivated, the motor will not run when the motor is otherwise capable of operating properly.

During the first method described above, when the Fault Logic Circuitry 144 determines a Motor Selected Start Delay 292 is in process, see FIG. 7, the Fault Logic Circuitry 144 immediately monitors Go Command 294, concurrently verifying motor currents for Selected Motor Current 298, 300 and no current for unselected motors via Selected Motor Current 298, 300 until the GO switch or pushbutton 88 (see FIG. 1) is deactivated or the Selected Motor is deselected. If the Selected Motor Current 298, 300 does not detect the proper current status, it sets the Set Fault Data Latch 308 sending a Set Kill via the Buffer Driver Set Kill 312 to Set Kill (see FIG. 6, box 270) and illuminates the appropriate fault via the Buffer Driver Illuminate Selected Motor Fault LED 314 and sends a Network Cascade Fault to interconnected controllers via the connector Controller Network Fault 124. If Go Command 294 is false, the Fault Logic Circuitry 144 checks the status of Current Array 144 for Go Command activity via the logic loop of Check next Motor for Current 302, Motor Current 318, and All Motors Checked 310. If there is no motor activity, the Fault Logic Circuitry 144, Wait for Selected Motor 320, waits for a change in status of Selected Motor. If the logic loop of Check next Motor For Current 302, Motor Current 318, All Motors Checked 310 detects motor current, Motor Current 318 sets the Set Fault Data Latch 316 sending a Set Kill via the Buffer Driver Set Kill 312 to Set Kill 270 (see FIG. 6), illuminates the appropriate fault via the Buffer Driver Illuminate Selected Motor Fault LED 314 and sends a Network Cascade Fault to interconnected controllers via the connector Controller Network Fault 124.

When the Fault Logic Circuitry 144 determines a Go Start Delay 290 is in process, it immediately checks to see if the Motor Selected 296 is true and verifies the status of Selected Motor Current 304. If Selected Motor Current is true, the Fault Logic Circuitry 144 continues to monitor the status of the Current Array 140, GO switch or pushbutton 88 and Motor Up/Off/Down Switches 54, 56, 58, 60 for changes. If a Selected Motor Current goes false and GO switch or pushbutton 88 is active, it generates a Set Fault Data Latch 316 sending a Set Kill via the Buffer Driver Set Kill 312 to Set Kill 270 (see FIG. 6) and illuminates the appropriate fault via the Buffer Driver Illuminate Motor Fault LED 314 and sends a Network Cascade Fault to interconnected networked controllers via the connector Controller Network Fault 124. If Motor Selected 296 is false, the Fault Logic Circuitry 144 immediately checks the Selected Motor Current. If Selected Motor Current is false, the Fault Logic Circuitry 144 continues to monitor the status of the Current Array 140, GO switch or pushbutton 88 and Motor Up/Off/Down Switches 54, 56, 58, 60 for changes while Wait For Go 306. If Motor Current 318 is true, an immediate set fault is sent to Set Fault Data Latch 316 sending a Set Kill via the Buffer Driver Set Kill 312 to Set Kill 270 (see FIG. 6) and illuminates the appropriate fault via the Buffer Driver Illuminate Selected Motor Fault LED 314 and sends a Network Cascade Fault to interconnected networked controllers via the connector Controller Network Fault 124.

Selected Motor/Go Turn-Off Failure FIG. 8 flowchart details the logic for motor turn-off and motor turn-off failure. A motor can be normally turned off in one of at least two ways. The first and most common is to release the GO switch or pushbutton 88 deactivating the Go Command. The second way to turn-off a motor is by setting the Up/Off/Down switch to the off position thereby deselecting the motor. Go Turn-Off Delayed 216 is generated in FIG. 3 and enters FIG. 8 Go Turn-Off Delayed 324. The Fault Logic Circuitry 144, Motor Selected 326 determines if there are any selected motors via logic loop Check N motors for Current 330, Motor Not Current 334 Motors Checked 338 and Goto Start 348. If Motor Selected 326 is true, the Selected Motor Not Current 332 is checked at the end of the Turn-Off Delayed. If Selected Motor Not Current 332 is true, it indicates that a motor runaway has occurred and a set fault is sent to Set Fault Data Latch 340 Latch sending a Set Kill via the Buffer Driver Set Kill 346 to Set Kill 270 (see FIG. 6) and illuminates the appropriate fault via the Buffer Driver Illuminate Selected Motor Fault LED 314, 344 and sends a Network Cascade Fault to interconnected controllers via the connector Controller Network Fault 124. If Selected Motor Not Current 332 is true, it indicates that the motor stopped as it should have and the Fault Logic Circuitry goes into a standby mode via Goto Start 348 to wait for new commands. If the Motor Selected 326 is false, the Fault Logic Circuitry 144 checks all of the motors to verify that there are no motors running via the logic loop Check N Motors for Current 330 (where N represents the number of motors the controller is designed to handle), Motor Not Current 334, and N Motors Checked 338. If Motor Not Current is false, it indicates that a motor runaway has occurred and a set fault is sent to Set Fault Data Latch 340 sending a Set Kill via the Buffer Driver Set Kill 346 to Set Kill 270 (see FIG. 6) and illuminates the appropriate fault via the Buffer Driver Illuminate Selected Motor Fault LED 314 and sends a Network Cascade Fault to interconnected controllers via the connector Controller Network Fault 124. If N Motors Checked is true, it indicates that all the motors have been checked and Fault Logic Circuitry 144 goes to Goto Start 348 to standby for new commands.

Any selected motor can be turned off by placing the Motor Up/Off/Down Switch 54, 56, 58, 60 to the off position initiating a Motor Deselected Turn-Off Delayed 322 (see FIG. 8). The Fault Logic Circuitry 144 checks Selected Motor Not Current 328 and if false, sends a set fault to Set Fault Data Latch 336 sending a Set Kill via the Buffer Driver Set Kill 346 to Set Kill 270 (see FIG. 6) and illuminates the appropriate fault via the Buffer Driver Illuminate Selected Motor Fault LED 314 and sends a Network Cascade Fault to interconnected controllers via the connector Controller Network Fault 124 If Selected Motor Not Current 328 is true, the Fault Logic Circuitry 144 goes to Goto Start 348 to wait for new commands.

FIG. 9 shows a Conditional Faults flowchart showing inputs for external faults to be processed by the Fault Logic Circuitry 144. The Fault Logic Circuitry 144 has the capability to process three distinct types of faults, namely, a Network Cascade Fault, a Load Cell Fault, and an Auxiliary Fault. A Controller Network Fault is sent to the Portable Chain Hoist Motor Controller with Integrated Fault Monitoring System 138 via connector 122 to FIG. 9 as Cascade In 352 immediately setting Set Cascade Fault Latch sending a Set Kill 370 to Set Kill 270 (see FIG. 6) immediately shutting off AC power to the Motor and illuminating the Controller Network Fault LED 110 via Illuminate/Clear Cascade Fault LED 372. The Controller Network Fault is sent downstream to the next interconnected Portable Chain Hoist Motor Controller with Integrated Fault Monitoring System 138 via Network Controller Out Socket 124 (see FIG. 1). The controller network fault is reset by activating either Reset Pushbutton 86 or 108 (see FIG. 1) resetting the Cascade Fault Latch 358, Latching Relay 276, and turning off the Controller Network Fault LED 110.

Referring again to FIG. 9, Auxiliary Fault In 354 provides for special configurations for various monitoring devices. Any monitoring device that can sink 10 ma is capable of generating an Auxiliary Fault. The Fault Logic Circuitry 144 receives auxiliary fault inputs AUX. 170, 172, 174, 176 via Auxiliary Connector 116 that set the appropriate Auxiliary Fault Latch 360 sending a Set Kill 370 to Set Kill 270, as described above with reference to FIG. 6, immediately shutting off AC power to the Motor and illuminating Auxiliary Fault Led 120 via Illuminate/Clear Auxiliary Fault LED 374. The auxiliary fault may be reset by activating either Reset Pushbuttons 86 or 108 (see FIG. 1) resetting the Reset Auxiliary Fault Latch 366, Latching Relay 276, and turning off the Auxiliary Fault LED 120. Portable Chain Hoist Motor Controller with Integrated Fault Monitoring System 138 has external inputs for load cells via Load Cell Connector 118 (see FIG. 1) that connect to the Fault Logic Circuitry 144, Load Cell Fault In 356. Any load cell device that can sink 10 ma is capable of generating a Load Cell Fault immediately shunting off AC power to the Motors via Set Kill 370 and illuminating the appropriate Load Cell Fault 114 via Illuminate/Clear Load Cell Fault LED 376. The load cell fault is reset by activating either Reset Pushbuttons 86 or 108 (see FIG. 1) resetting the Reset Load Cell Fault Latch 368, Latching Relay 276, and turning off the appropriate Load Cell Fault Led 114. The Set Load Cell Fault Latch 362 is set by Load Cell Fault In 356 immediately shunting off AC power to the Motors via Set Kill 370 and illuminating the appropriate Load Cell Fault 114 via Illuminate/Clear Load Cell Fault LED 374. The auxiliary fault is reset by activating either Reset Pushbuttons 86 or 108 (see FIG. 1) resetting the Reset Load Cell Fault Latch 368, Latching Relay 276, and turning off the appropriate Auxiliary Fault Led 114.

Latching Relay 276 is set via any of the Set Kill 270 or via the Kill pushbutton 90, 102 via Kill 268 illuminating the Illuminate/Clear Kill LED 280 killing AC power via 12 VDC Kill Relay Drive 284 to all motors and illuminating the Reset Pushbuttons 86, 108 and driving a Network Cascade Fault 282. Clearing the fault condition may be accomplished via Reset Pushbutton command 266 by, for example, depressing the Reset Pushbutton 86 on the Handheld Controller 48 or reset pushbutton 108 on the face panel 18 generating a Reset Command 266 resetting the Latching Relay via the Reset Latching Relay 274 driver circuitry.

Power on reset 286 is generated when the circuit breakers 44, 46 are activated turning on the +12 VDC Power Supply 272 that powers the DC-DC 12 VDC to 5 VDC converter 275 providing power to 5 VDC Logic and Display 288 and resetting all the fault latches and generating a Reset Latching Relay 274.

Referring finally to FIG. 14, FIG. 14 is an exemplifying, non-limiting flow chart showing one embodiment of fault troubleshooting in accordance with the invention that incorporates various steps described above. Accordingly, the process begins at 400 to troubleshoot the fault that occurred, i.e., identify where the fault is. At step 402, fault indicators are examined, i.e., indicators 98, 100, 110, 114, 120 shown in FIG. 1, to determine the type of fault. A determination is made at 404 as to whether a controller network fault is indicated. If so, at 406, fault indicators 90, 92, 94, 96, 100, 114, 120 are examined on all interconnected controllers in the network. Then, at 408, the fault troubleshooting described elsewhere in FIG. 14 is performed for all controllers with an initial fault.

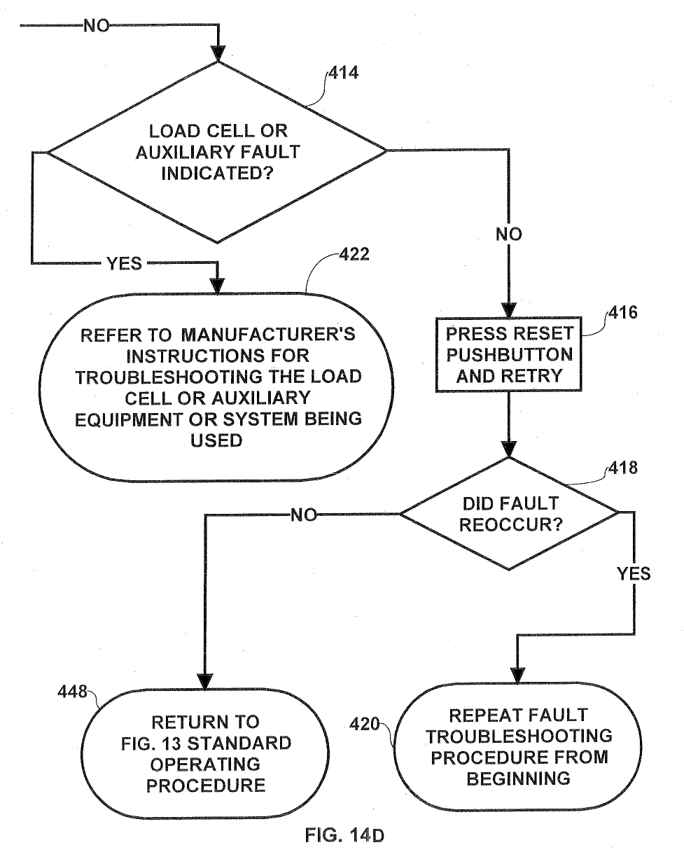

If a controller network fault is not indicated at 404, a determination is made at 410 as to whether a motor loss/limit fault is indicated. If not, a determination is made at 412 as to whether a runaway fault is indicated. If not, a determination is made at 414 as to whether a load cell or auxiliary fault is indicated. If not, the troubleshooter is directed at 416 to press the reset button and retry the fault troubleshooting. A determination is then made at 418 as to whether the fault reoccurred and if not, there is no fault in the system and the system can return to its standard operating procedure, step 448, with reference to FIG. 13. If a fault has reoccurred at step 418, the fault troubleshooting is repeated, step 420, by proceeding to the start 400.

If the determination at step 414 indicates that a load cell or auxiliary fault is indicated, the troubleshooter is directed to refer to the manufacturer's instructions for troubleshooting the load cell or auxiliary equipment or the system being used, at 422.

If the determination at step 410 indicates that a motor loss/limit fault is indicated, the troubleshooter is directed to identify the hoist which had a fault occur and its direction of travel, at 424, and place all other hoist toggle switches, i.e., Motor Up/Off/Down switches 54, 56, 58, 60 (see FIG. 1) in an off position, step 426. The troubleshooter is then directed to select switch in the opposite direction for the hoist which indicated a fault, step 428, push the Reset pushbutton(s) 86, 108 (see FIG. 1), step 430, and quickly press and release the GO switch or pushbutton 88 (see FIG. 1), step 432. A determination is made at 434 as to whether the fault reoccurred, and if not, the motor limit fault prevents the hoist from reaching its upper or lower travel limit, step 436.

If the fault has reoccurred, from step 434, or when a runaway fault is indicated at 412, the troubleshooter is directed to replace the motor cable at 438, push the Reset pushbutton(s) 86, 108 (see FIG. 1), step 440, and quickly press and release the GO switch or pushbutton 88 (see FIG. 1), step 442. A determination is made at 442 as to whether the fault reoccurred, and if not, the fault has been resolved (by replacement of the motor cable), step 446 and the system can return to its standard operating procedure, step 448, with reference to FIG. 13.

If the fault has reoccurred, then the troubleshooter is directed to replace or repair the hoist at 450, push the Reset pushbutton(s) 86, 108 (see FIG. 1), step 452, and quickly press and release the GO switch or pushbutton 88 (see FIG. 1), step 454. A determination is made at 456 as to whether the fault reoccurred, and if not, the fault has been resolved (by replacement or repair of the hoist), step 446 and the system can return to its standard operating procedure, step 448, with reference to FIG. 13.

If the fault has reoccurred, the user is directed at 458 to troubleshoot the Chain Hoist Motor Controller with Integrated Fault Monitoring System 2 and/or the control pendant 48 (See FIG. 1).

Having described exemplary embodiments of the invention with reference to the accompanying drawings, it will be appreciated that the present invention is not limited to those embodiments, and that various changes and modifications can be effected therein by one of ordinary skill in the art without departing from the scope or spirit of the invention as defined by the appended claims.

We claim:

1. A fault monitoring system, comprising:
at least one current sensor or current operated switch, each monitoring an individual phase on at least one electric single or poly-phase motor; and
a fault monitoring unit coupled to said at least one current sensor or current operated switch and that detects a fault of the at least one electric motor,
said fault monitoring unit being configured to:
detect correct operation of each of the at least one electric motor;
detect a failure of any one of the at least one motor to operate when a commanded movement signal has been given to that motor; and
detect loss of electrical phase on any active one of the at least one motor prior to being commanded to stop operating.

2. The system of claim 1, wherein said fault monitoring unit is integrated internally with at least one electric chain hoist motor controller.

3. The system of claim 1, where said fault monitoring unit is coupled externally to at least one electric chain hoist motor controller.

4. An arrangement, comprising:
a plurality of interconnected electric chain hoists, each of said electric chain hoists including at least one electric chain hoist motor controller,
wherein said fault monitoring system of claim 1 is coupled to said electric chain hoist motors such that said fault monitoring unit is coupled externally to said electric chain hoist motor controller of each of said electric chain hoists or is integrated internally with said at least one electric chain hoist motor controller of each of said electric chain hoists,
said fault monitoring unit being further configured to provide a power disconnection or automatic emergency stop to all of said interconnected electric chain hoists or electric chain hoist motor controllers when a fault has been detected by said fault monitoring system.

5. The system of claim 1, wherein said fault monitoring unit provides fault specific data to at least one of a data logger, an indicator array, a display device, and an audible device when a fault has been detected by said fault monitoring system.

6. The system of claim 1, wherein said fault monitoring unit is further configured to detect failure of the at least one electric motor to stop operating when a movement command has been deactivated.

7. The system of claim 1, wherein said fault monitoring unit is further configured to detect movement of the at least one motor when a movement command has not been given.

8. The system of claim 1, wherein said fault monitoring unit is further configured to send a signal indicative of detection of a fault of the at least one electric motor to an additional fault monitoring system coupled thereto, the additional fault monitoring system being configured to monitor other electric chain hoists or electric chain hoist motor controllers.

9. The system of claim 8, wherein said fault monitoring unit is further configured to detect a fault from the additional fault monitoring system coupled thereto.

10. The system of claim 1, wherein said fault monitoring unit is further configured to detect a fault signal from at least one auxiliary device coupled to said fault monitoring system.

11. The system of claim 1, where said fault monitoring unit is further configured to detect a fault signal from at least one load detecting device coupled to said fault monitoring system.

12. The system of claim 1, wherein said fault monitoring unit comprises circuitry that detects power supply phase rotation with automatic and/or manual phase reversing capabilities.

13. An arrangement, comprising:
a plurality of interconnected electric chain hoists, each of said electric chain hoists including at least one electric chain hoist motor controller,
wherein said fault monitoring system of claim 1 is coupled to said electric chain hoist motors such that said fault monitoring unit is coupled externally to said electric chain hoist motor controller of each of said electric chain hoists or is integrated internally with said at least one electric chain hoist motor controller of each of said electric chain hoists,
said fault monitoring unit comprising circuitry that detects over-voltage and under-voltage monitoring and provides a power disconnection or automatic emergency stop to all of said interconnected said electric chain hoists.

14. The system of claim 1, wherein said fault monitoring unit comprises circuitry that provides a power on reset to said fault monitoring unit.

15. The system of claim 1, further comprising a fault monitoring override device coupled to said fault monitoring unit and that is configured to allow individual control of at least one electric chain hoist associated with said system with a control pendant connected directly to said at least one electric chain hoist.

16. The system of claim 1, further comprising at least one control pendant coupled to said fault monitoring unit and includes at least one of a fault indicator, an audible alarm, a display and pushbuttons/switches.

17. The system of claim 1, wherein said fault monitoring unit further comprises a reset pushbutton or switch that is configured to reset said fault monitoring unit upon depression or actuation.

18. The system of claim 1, further comprising a self-test unit that is configured to check operability or functionality of said fault monitoring unit.

19. An arrangement, comprising:
a plurality of interconnected electric chain hoists, each of said electric chain hoists including at least one electric single or poly-phase motor and an electric chain hoist motor controller therefore;
current sensors or current operated switches, each monitoring an individual phase on a respective one of said electric motors of said electric chain hoists; and
a fault monitoring unit coupled to said current sensors or said current operated switches and that detects a fault of any of said electric motors and generates a fault signal in response to the detection of a fault,
said fault monitoring unit being configured to:
detect a failure of any of said electric motors to operate when a commanded movement signal has been given to that motor thereby causing generation of the fault signal;
detect loss of electrical phase on any active one of said electric motors prior to being commanded to stop operating thereby causing generation of the fault signal; and
provide a power disconnection or automatic emergency stop to all of said interconnected electric chain hoists or electric chain hoist motor controllers when a fault signal has been generated by said fault monitoring unit.

20. The arrangement of claim 19, wherein said fault monitoring unit comprises circuitry that detects over-voltage and under-voltage monitoring and provides a power disconnection or automatic emergency stop to all of said interconnected said electric chain hoists.

21. The arrangement of claim 19, wherein said fault monitoring unit comprises a switchable relay that reacts to generation of the fault signal by said fault monitoring unit and generates a kill signal that in turns generates a power disconnect to all interconnected electric chain hoists.

22. The arrangement of claim 19, wherein said fault monitoring unit is configured to output fault specific diagnostic data based on the generated fault signal to enable identification of a type of the detected fault.
